(19) United States
(12) Patent Application Publication
(10) Pub. No.: US 2025/0373017 A1
(43) Pub. Date: Dec. 4, 2025

(54) TRANSMISSION AND DISTRIBUTION-INTEGRATED POWER NETWORKS

(71) Applicant: Hitachi, Ltd., Tokyo (JP)

(72) Inventors: Yoshihisa OKAMOTO, San Jose, CA (US); Bo Yang, Santa Clara, CA (US); Panitarn Chongfuangprinya, San Jose, CA (US)

(21) Appl. No.: 18/733,638

(22) Filed: Jun. 4, 2024

(51) Int. Cl. H02J 3/06; G01R 21/133; H02J 3/00; H02J 3/38

(52) U.S. Cl. CPC H02J 3/06; G01R 21/133; H02J 3/003; H02J 3/004; H02J 3/38; H02J 2203/10

(57) ABSTRACT

Systems and methods facilitate cooperation between transmission and distribution grids to optimize power flow and grid planning. Grid equipment data along with demand and renewable energy information are analyzed over a designated planning period to generate grid measure data, which is then used to create various grid configurations. These configurations are processed to determine power flows and boundary condition data for both transmission grids and distribution grids. The resulting data is utilized to calculate optimal grid configurations and power flows, which are then evaluated for investment and operational costs. Costs are compared to determine differential costs for each configuration, aiding in the development of an economically efficient grid plan. Advantageously, the systems and methods optimize grid configurations based on time-series data, while satisfying reliability standards, enhancing grid stability and performance, and maintaining cost-effectiveness.

### BACKGROUND

### Field

The present disclosure is generally directed to power distribution networks, and more specifically, to systems and methods for improving cooperation between power transmission and distribution utilities.

### Related Art

In order to maintain stable power supply, transmission and distribution utilities develop grid plans spanning 10 to 20 years, taking into account various factors such as aging grid infrastructure, rising electricity demand, and increased availability of renewable energy (RE) sources. Typically, utilities develop their plans independently from each other to maximize their economic gains while striving to maintain grid reliability.

As the introduction of RE sources at the grid edge is accelerating in pursuit of achieving carbon neutrality, investments in the distribution grid may have an impact on the transmission grid. For example, by increasing RE sources in the distribution grid and reducing the reliance on power from the transmission grid, it is possible to prevent transmission grid overload and reduce the need for further investments in transmission grids.

Therefore, integration methods aimed at improving the cooperation between power transmission and distribution utilities should lead to an increase in grid-wide economic efficiencies. Accordingly, it is desirable to have integrated transmission and distribution planning systems and methods that can accomplish this objective, while solving related problems. FIGS. 1A and 1B demonstrates technical challenges of existing designs.

A primary issue related to collaborative planning involves the necessity of information sharing between transmission grids and distribution grids. As depicted in FIGS. 1A and 1B, when utilities in charge of each grid are different entities, confidentiality issues can complicate the sharing of potentially sensitive data. Further, even if data could be freely shared among utilities, the vast amount of data involved can make grid-wide collaborative planning difficult. Thus, it is also desirable to limit the amount of to-be-shared data accordingly.

A related challenge involves the necessity of analyzing and evaluating all possible grid configurations to ensure economically sound planning. However, given the complexity of grid configurations for a multitude of grids, the computational burden associated therewith increases exponentially. This further exacerbates the challenges in developing plans in a reasonable amount of time. Therefore, it is also desirable to reduce the number of to-be-analyzed potential grid configurations to a better manageable size.

### SUMMARY

Transmission and distribution integrated planning systems and methods for cooperative planning invoice three main components: a planning component that formulates grid configurations, an analysis component that calculates optimal power flow, and an evaluation component that calculates investment and operation cost and formulates grid plans. Their interaction aims to generate the most economically rational grid plan within a planning period while limiting shared information and strategically reducing the number of to-be-analyzed grid configurations among various possible grid configurations.

The analysis component computes, for the distribution grid, an optimal power flow for every grid configuration that has been generated by the planning component, e.g., for each predetermined unit time and based on demand and RE scenarios. In addition, the analysis component may obtain power flow data that has been generated at transmission grid boundaries and share that data with the transmission grid.

The analysis component selects, for the transmission grid, optimal grid configurations among those generated by the planning component for each predetermined unit of time, e.g., based on demand and RE scenarios and the power flow at the distribution grid boundary. In addition, this component calculates optimal power flows for these configurations for the predetermined units of time.

The evaluation component computes, for the distribution grid, for each predetermined unit time, investment and operational costs for all grid configurations generated by the planning component, e.g., based on the optimal power flow calculated by the analysis component. In further computes a cost differential for each grid configuration from the initial grid configurations and shares this with the transmission grid. For the transmission grid, the evaluation component computes investment and operation cost for all grid configurations generated by the planning component for each predetermined unit time based on the optimal power flow calculated by the analysis component and the differential cost of the distribution grid. In addition, the evaluation component computes the cost differential for each grid configuration from the initial grid configurations and shares these with the distribution grid.

For both grid types, the evaluation component generates the most economically rational time-series transition of the grid configuration throughout the planning period based on the investment and operation cost of the own grid and the differential cost of the other connected grids, evaluated by the evaluation component. In addition, the evaluation component determines a grid plan based on the time-series transition of the grid configuration.

In some aspects of the disclosure, a grid planning method for transmission and distribution grids, includes: at a planning component, performing steps for each of a transmission grid and a distribution grid, the steps including: in response to receiving grid equipment data and receiving demand and RE information associated with a planning period, generating grid measure data; using the grid measure data to generate grid configurations; and communicating the grid configurations to an analysis component; at the analysis component, performing steps for the distribution grid, the steps including: in response to receiving the grid configurations, determining, for each grid configuration, a first set of power flows for predetermined units of time within the planning period; using the power flows to obtain boundary condition data associated with boundaries between the distribution grid and the transmission grid; and communicating the first set of power flows to a distribution-side evaluation component; at the analysis component, performing steps for the transmission grid, the steps including: in response to receiving the grid configurations and the boundary condition data, generating, for each grid configuration, frame grid configuration data; using the frame grid configuration data to calculate optimal grid configuration data; using the optimal grid configuration data to generate a second set of power flows; and communicating the second set of power flows to a transmission-side evaluation component; at the distribution-side evaluation component and the transmission-side evaluation component, performing steps including: in response to receiving the grid configurations and respective first set of power flows and second set of power flows, generating investment cost and operation cost data; computing and exchanging a differential cost for each grid configuration; and using the investment cost and operation cost data and the differential cost to generate a grid plan.

In some aspects, the techniques described herein relate to a non-transitory computer-readable medium for storing instructions for executing a process, the instructions including: in response to receiving grid equipment data and demand and RE information associated with a planning period, generating grid measure data; using the grid measure data to generate grid configurations; determining, for each grid configuration, a first set of power flows for predetermined units of time within the planning period; using the power flows to obtain boundary condition data associated with boundaries between the distribution grid and the transmission grid; and in response to receiving the grid configurations and the boundary condition data, generating, for each grid configuration, frame grid configuration data; using the frame grid configuration data to calculate optimal grid configuration data; using the optimal grid configuration data to generate a second set of power flows; in response to receiving the grid configurations and respective first set of power flows and second set of power flows, generating investment cost and operation cost data; computing and exchanging a differential cost for each grid configuration; and using the investment cost and operation cost data and the differential cost to generate a grid plan.

In some aspects, the techniques described herein relate to an apparatus, including: one or more processors, configured to perform steps including: at a planning component, performing steps for each of a transmission grid and a distribution grid, the steps including: in response to receiving grid equipment data and receiving demand and renewable energy RE information associated with a planning period, generating grid measure data; using the grid measure data to generate grid configurations; and communicating the grid configurations to an analysis component; at the analysis component, performing steps for the distribution grid, the steps including: in response to receiving the grid configurations, determining, for each grid configuration, a first set of power flows for predetermined units of time within the planning period; using the power flows to obtain boundary condition data associated with boundaries between the distribution grid and the transmission grid; and communicating the first set of power flows to a distribution-side evaluation component; at the analysis component, performing steps for the transmission grid, the steps including: in response to receiving the grid configurations and the boundary condition data, generating, for each grid configuration, frame grid configuration data; using the frame grid configuration data to calculate optimal grid configuration data; using the optimal grid configuration data to generate a second set of power flows; and communicating the second set of power flows to a transmission-side evaluation component; at the distribution-side evaluation component and the transmission-side evaluation component, performing steps including: in response to receiving the grid configurations and respective first set of power flows and second set of power flows, generating investment cost and operation cost data; computing and exchanging a differential cost for each grid configuration; and using the investment cost and operation cost data and the differential cost to generate a grid plan.

Aspects of the present disclosure can involve a system, which can involve means for receiving grid equipment data and demand and RE information associated with a planning period, generating grid measure data; means for using the grid measure data to generate grid configurations; means for determining, for each grid configuration, a first set of power flows for predetermined units of time within the planning period; means for using the power flows to obtain boundary condition data associated with boundaries between the distribution grid and the transmission grid; and means for, in response to receiving the grid configurations and the boundary condition data, generating, for each grid configuration, frame grid configuration data; using the frame grid configuration data to calculate optimal grid configuration data; means for using the optimal grid configuration data to generate a second set of power flows; in response to receiving the grid configurations and respective first set of power flows and second set of power flows, means for generating investment cost and operation cost data; means for computing and exchanging a differential cost for each grid configuration; and means for using the investment cost and operation cost data and the differential cost to generate a grid plan.

### BRIEF DESCRIPTION OF DRAWINGS

FIGS. 1A and 1B illustrate technical problems in existing designs.

FIG. 2 illustrates a system for facilitating cooperation between transmission grids and distribution grids according to various embodiments of the present disclosure.

FIG. 3 illustrates additional details of the system shown in FIG. 2.

FIG. 4A illustrates an exemplary process for a planning component on a distribution side of a grid according to various embodiments of the present disclosure.

FIG. 4B illustrates an exemplary process for process for a planning component on a transmission side of a grid according to various embodiments of the present disclosure.

FIG. 5A illustrates an exemplary current grid configuration according to various embodiments of the present disclosure.

FIG. 5B illustrates possible future grid configurations generated based on FIG. 5A.

FIG. 6A illustrates exemplary current grid configuration according to various embodiments of the present disclosure.

FIG. 6B illustrates possible future grid configurations generated based on FIG. 6A.

FIG. 7A illustrates an exemplary process for an analysis component on a distribution side of a grid according to various embodiments of the present disclosure.

FIG. 7B illustrates an exemplary process for an analysis component on a transmission side of a grid according to various embodiments of the present disclosure.

FIG. 8A illustrates an exemplary process for an evaluation component on a distribution side according to various embodiments of the present disclosure.

FIG. 8B illustrates an exemplary process for an evaluation component on a transmission side according to various embodiments of the present disclosure.

FIG. 9 illustrates an example frame grid configuration according to various embodiments of the present disclosure.

FIG. 10 illustrates an example computing environment according to various embodiments of the present disclosure.

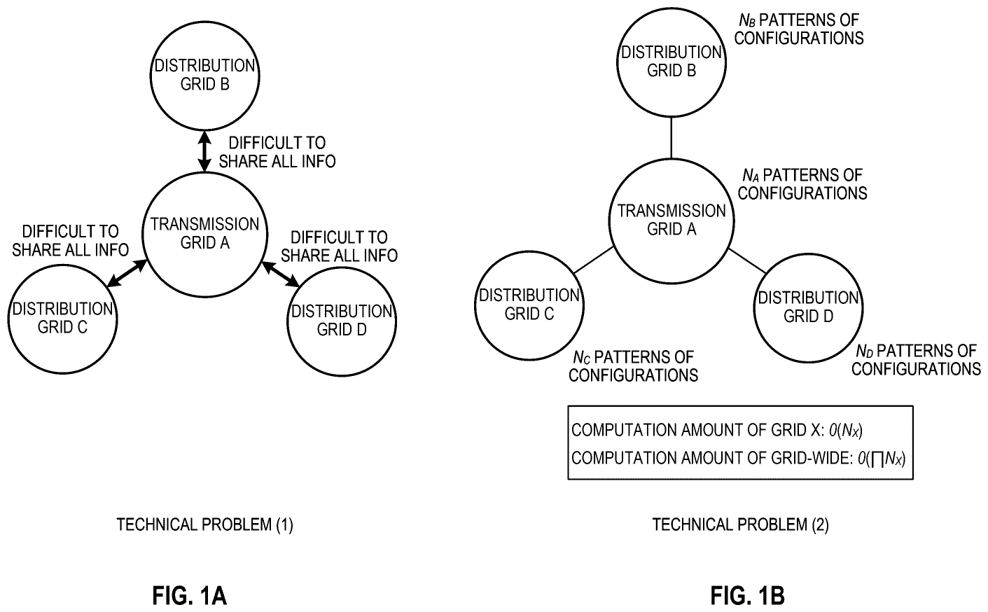

### DETAILED DESCRIPTION

The following detailed description provides details of the figures and example implementations of the present application. Reference numerals and descriptions of redundant elements between figures are omitted for clarity. Terms used throughout the description are provided as examples and are not intended to be limiting. For example, the use of the term “automatic” may involve fully automatic or semi-automatic implementations involving user or administrator control over certain aspects of the implementation, depending on the desired implementation of one of ordinary skill in the art practicing implementations of the present application. Selection can be conducted by a user through a user interface or other input means, or can be implemented through a desired algorithm. Example implementations as described herein can be utilized either singularly or in combination and the functionality of the example implementations can be implemented through any means according to the desired implementations.

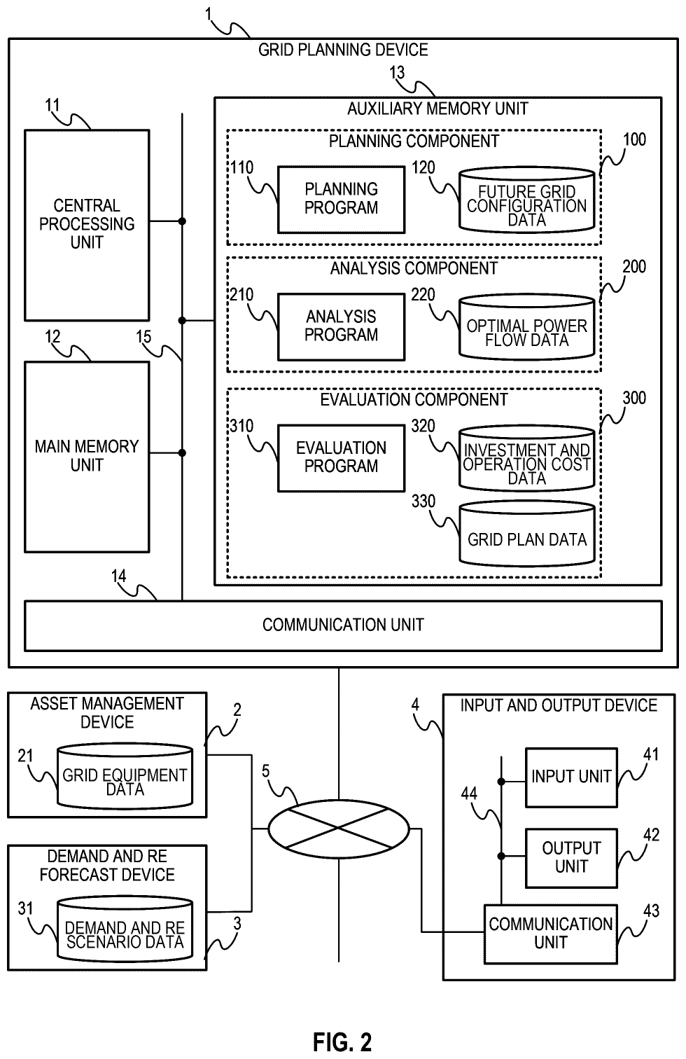

FIG. 2 illustrates a system for facilitating cooperation between distribution grids and transmission grids according to various embodiments of the present disclosure. In embodiments, grid planning system 200 generates grid plans for transmission and distribution grids. As shown in FIG. 2, grid planning system 200 is configured by connecting grid planning device 1, asset management device 2, demand and RE forecast device 3, and input and output device 4 via network 5.

Grid planning device 1 is configured by connecting central processing unit 11, main memory unit 12, auxiliary memory unit 13, and communication unit 14 via internal bus 15. Central processing unit 11 is a CPU that controls the grid planning device 1 and performs computations. Main memory unit 12 temporarily stores various programs and data. Auxiliary memory unit 13 is a hard disk that stores various programs and data for a relatively long period of time. Communication unit 14 is implemented as a LAN cable or similar that facilitates communication with the asset management device 2, the demand and RE forecast device 3, and the input and output device 4 via the network 5.

Asset management device 2 and demand and RE forecast device 3 are computing devices that store information for use in generating plans by using the grid planning device 1. Input/output device 4 is configured by input unit 41, output unit 42, and communication unit 43 connected via an internal bus 44. Input unit 41 is a mouse, keyboard, or the like used by a user to input information when generating plans using the grid planning device 1. Output unit 42 is a display or the like used by the user to output information necessary for generating plans using the planning device 1. Communication unit 43 is a LAN cable or similar that facilitates communication with grid planning device 1, asset management device 2, and demand and RE forecast device 3, e.g., via network 5.

Individual programs stored in auxiliary memory unit 13 are loaded into main memory unit 12, e.g., by a user transmitting a command from the input unit 41 of the input and output device 4 that is executed by central processing unit 11. Individual data, output as execution results, are stored in auxiliary memory unit 13 and displayed on output unit 42 of input/output device 4.

Generally, planning component 100 within auxiliary memory unit 13 stores planning program 110, which generates future grid configuration data 120. Future grid configuration data 120 contains possible future grid configurations. Analysis component 200 generates optimal power flow data 220, which includes optimal power flow information for each predetermined unit time for each future grid configuration. Evaluation component 300 uses evaluation program 310 to generate investment and operation cost data 320 and grid plan data 330, which includes grid plans for a specified period in the future. Finally, investment and operation cost data 320 includes investment and operation cost for each predetermined unit time for each future grid configuration.

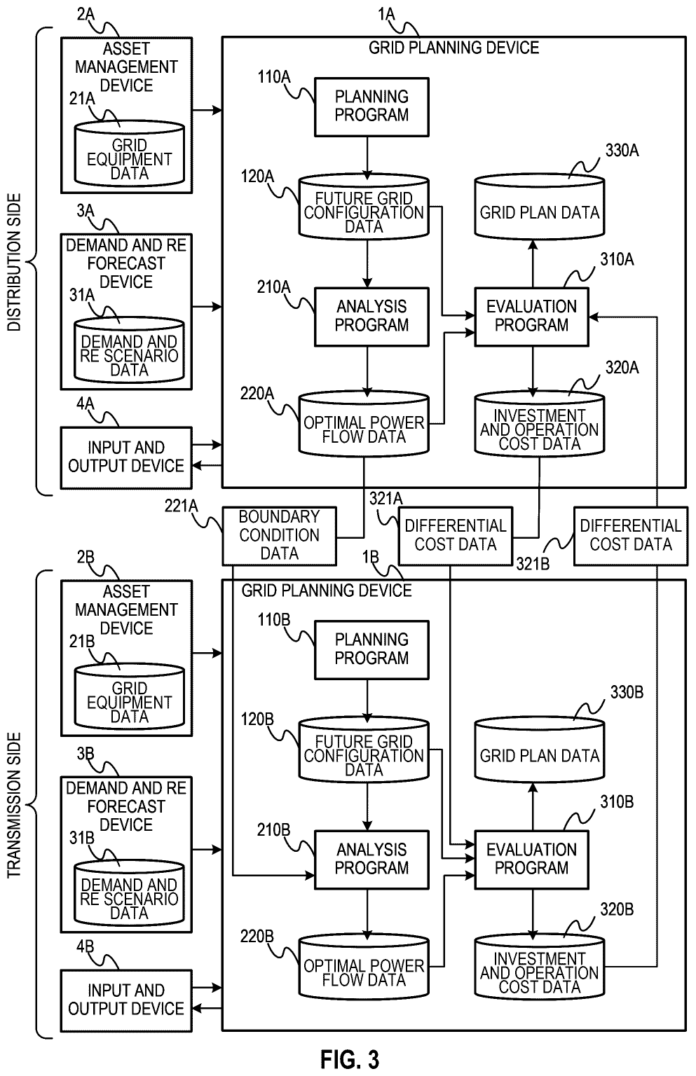

FIG. 3 illustrates additional details of the system shown in FIG. 2. In embodiments, the system configuration of grid planning device 1A of the distribution side of a grid is similar to the grid planning device 1B of the transmission side of the grid. However, their process flows may slightly differ. Their processing flows are depicted in FIG. 3.

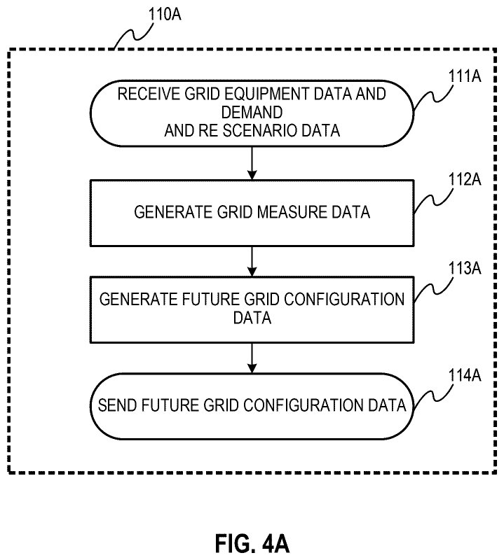

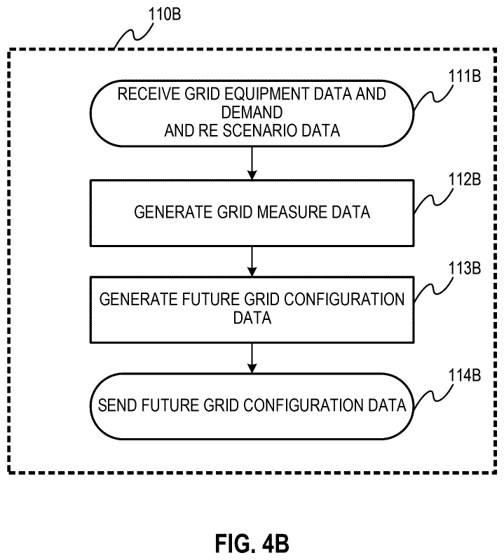

On the distribution side, planning program 110A generates future grid configuration data 120A based on grid equipment data 21A received from asset management device 2A and demand and RE scenario data 31A received from demand and RE forecast device 3A. Then, distribution planning program 110A communicates the generated future grid configuration data 120A to analysis program 210A and evaluation program 310A. Details of the process flow associated with planning program 110A at the distribution side are discussed in greater detail below with reference to FIG. 4A.

Similarly, planning program 110B at the transmission side generates future grid configuration data 120B, based on grid equipment data 21B received from asset management device 2B and demand and RE scenario data 31B received from demand and RE forecast device 3B, and sends future grid configuration data 120B to analysis program 210B and evaluation program 310B accordingly. Details of the process flow associated with planning program 110B at the transmission side are discussed in greater detail below with reference to FIG. 4B.

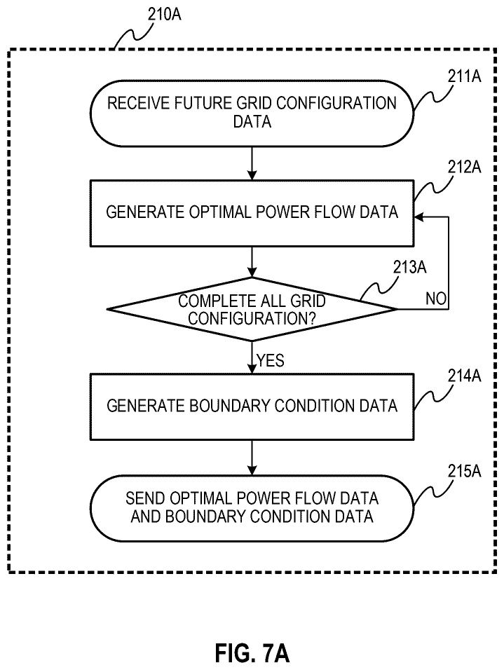

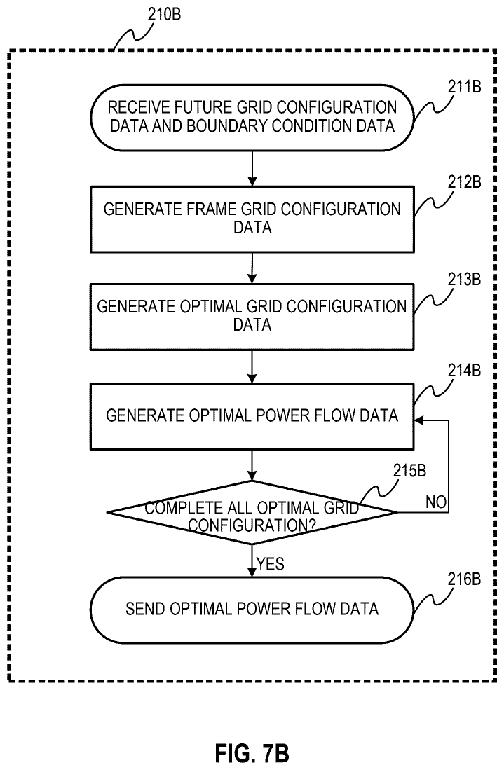

Analysis program 210A on the distribution side generates optimal power flow data 220A based on demand and RE scenario data 31A received from demand and RE forecast device 3A and future grid configuration data 120A received from planning program 110A. Then, analysis program 210A sends optimal power flow data 220A to evaluation program 310A. In addition, analysis program 210A extracts boundary condition data 221A from optimal power flow data 220A and sends the so obtained data to analysis program 210B located on the transmission side. Details of the process flow associated with analysis program 210A at the distribution side are discussed in greater detail below with reference to FIG. 7A.

Conversely, analysis program 210B on the transmission side generates optimal power flow data 220B based on demand and RE scenario data 31B received from demand and RE forecast device 3B, future grid configuration data 120B received from planning program 110B, and boundary condition data 221A received from analysis program 210A on the distribution side. Then, analysis program 210B communicates optimal power flow data 220B to evaluation program 310B. Details of the process flow associated with analysis program 210B at the transmission side are discussed in greater detail below with reference to FIG. 7B.

Evaluation program 310A on the distribution side generates investment and operation data 320A based on future grid configuration data 120A received from planning program 110A and optimal power flow data 220A received from analysis program 210A. In addition, it extracts differential cost data 321A from investment and operation cost data 320A and sends differential cost data 321A to evaluation program 310B on the transmission side. Evaluation program 310A further generates grid plan data 330A based on future grid configuration data 120A received from planning program 110A, investment and operation cost data 320A, and differential cost data 321B received from evaluation program 310B on the transmission side. The generated grid plan data 330A is stored in memory (not shown in FIG. 2).

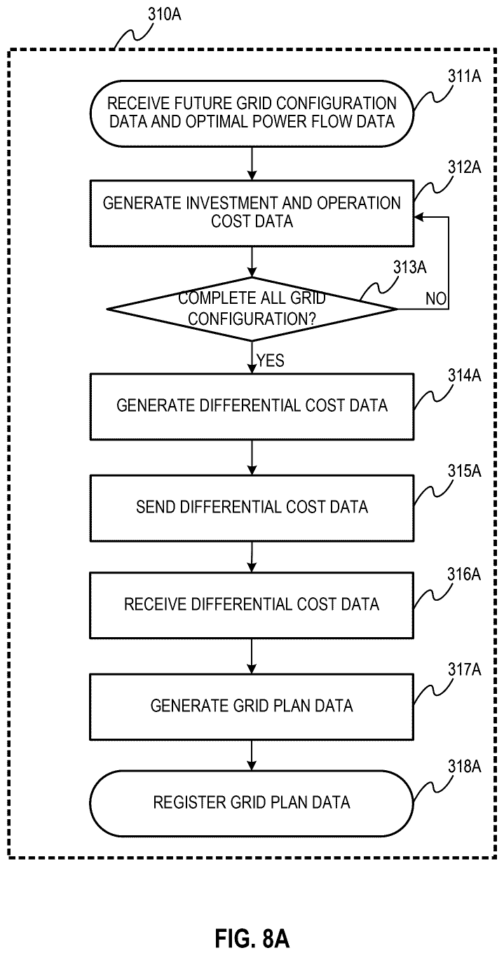

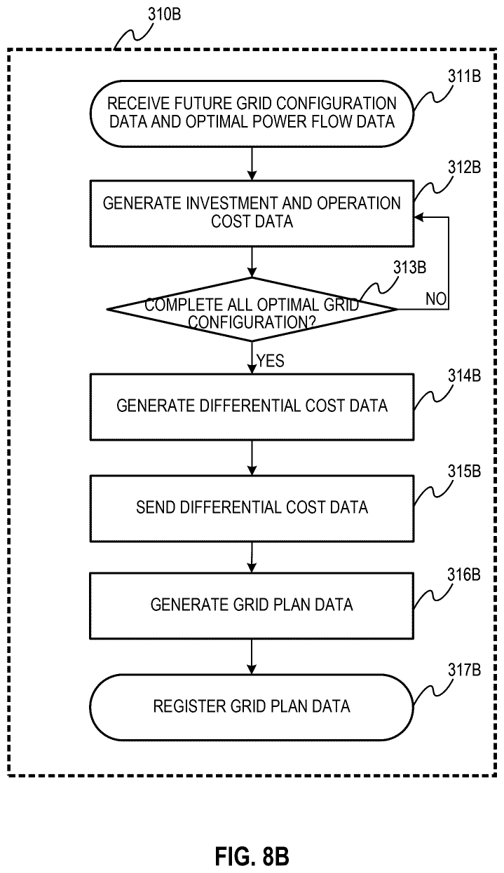

Details of the process flow associated with evaluation program 310A at the distribution side are discussed in greater detail below with reference to FIG. 8A.

Evaluation program 310B on the transmission side generates investment and operation data 320B based on future gird configuration data 120B received from planning program 110B, optimal power flow data 220B received from analysis program 210B, and differential cost data 321A received from evaluation program 310A on the distribution side. Then, evaluation program 310B extracts differential cost data 321B from investment and operation data 320B and sends the extracted data to evaluation program 310A on the distribution side. In addition, evaluation program 310B generates grid plan data 330B based on future grid configuration data 120B received from planning program 110B and investment and operation cost data 320B. Finally, evaluation program 310B stores grid plan data 330B in memory. Details of the process flow associated with evaluation program 310B at the transmission side are discussed in greater detail below with reference to FIG. 8B.

FIG. 4A illustrates an exemplary process for a planning component on a distribution side of a grid according to various embodiments of the present disclosure. Process 400 may begin at step 111A, when a planning program receives grid equipment data from an asset management device and demand and RE scenario data from the demand and RE forecast device.

At step 112A, the planning program generates grid measure data based on the grid equipment data and the demand and RE scenario data. By generating the grid measure data, the grid can meet predetermined reliability standards, such as load factor and voltage violation rates, even under future demand and RE scenarios. As shown in Table 1, grid measure data may comprise information that is related to planning-relevant questions such as “by when,” “which equipment,” and “what to do.”

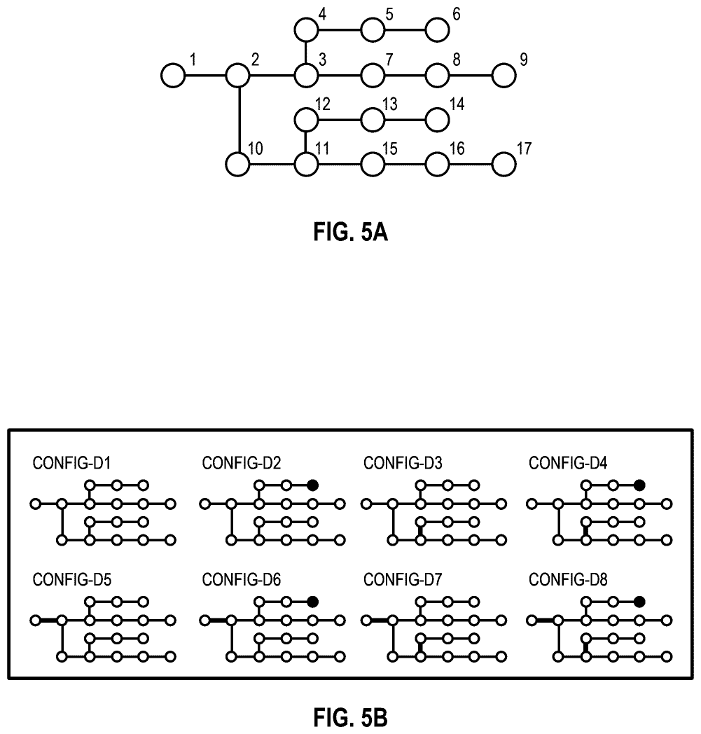

At step 113A, the planning program generates the future grid configuration data based on the grid measure data. Future configuration data is generated by implementing measures in combination for the current grid configuration, and it includes all possible future grid configurations as indicated in exemplary FIG. 5B. For example, if the grid measures in Table 1 are implemented for an exemplary current grid configuration, shown in FIG. 5A, the resulting eight future grid configurations (shown in FIG. 5B) are generated.

At step 114A, the planning program communicates the future grid configuration data to the analysis program.

TABLE 1
Grid measure data

| # | By when | Which equipment | What to do |
|---|---|---|---|
| 1 | 2032 | Line1-2 | Reinforce capacity |
| 2 | 2035 | Line11-12 | Replace |
| 3 | 2038 | Node6 | Install RE |

FIG. 4B illustrates an exemplary process for process for a planning component on a transmission side of a grid according to various embodiments of the present disclosure. Similar to FIG. 4A, process 450 in FIG. 4B may begin at step 111B, when the planning program receives grid equipment data from an asset management device and demand and RE scenario data from a demand and RE forecast device.

At step 112B, the planning program generates grid measure data based on the grid equipment data and the demand and RE scenario data. By generating the grid measure data, the grid can meet predetermined reliability standards such as load factor and voltage violation rates even under future demand and RE scenarios.

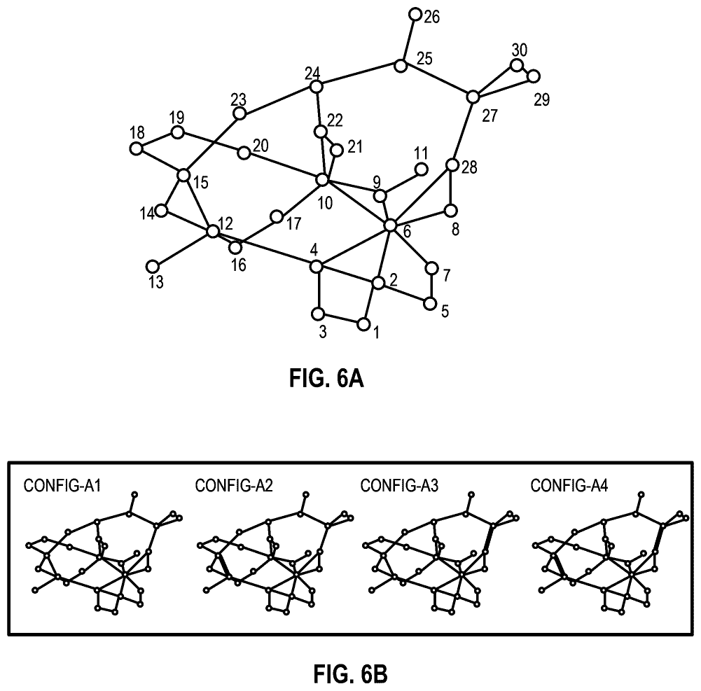

At step 113B, the planning program generates the future grid configuration data based on the grid measure data. Exemplary future configuration data (shown in FIG. 6A) is generated by implementing measures in combination for the current grid configuration and, as shown in exemplary FIG. 6B, includes all possible future grid configurations. For example, if the grid measures in Table 2 are implemented for the exemplary current grid configuration shown in FIG. 6A, the generated future grid configuration data will contain the four possible grid configurations shown in FIG. 6B.

At step 114B, the planning program communicates future grid configuration data to analysis program 210B.

TABLE 2
Grid measure data

| # | By when | Which equipment | What to do |
|---|---|---|---|
| 1 | 2033 | Line12-15 | Reinforce capacity |
| 2 | 2037 | Line27-28 | Replace |

FIG. 7A illustrates an exemplary process for an analysis component on a distribution side of a grid according to various embodiments of the present disclosure. Process 700 may begin at step 211A, when the analysis program receives the future grid configuration data from a planning program.

At step 212A, the analysis program generates optimal power flow data based on future grid configuration data. Optimal power flow data is generated by executing optimal power flow calculation for each grid configuration based on predetermined objective functions and constraint conditions. The optimal power flow data shown in Table 3 below includes, for each grid configuration, a time, power, voltage, and current associated with each object or equipment. A suitable objective function may be cost minimization, loss minimization, etc., and constraint conditions may include constraints associated with power flow, capacity, etc.

TABLE 3
Optimal power flow data

| Config | Time | Object | Power | Voltage | Current |
|---|---|---|---|---|---|
| Config-1 | 2030 Apr. 1 00:00 | Node1 | 15.1 MW | 12.0 kV | — |
| | | Line1-2 | 15.1 MW | — | 1.26 kA |
| | | . . . | . . . | . . . | . . . |
| | 2030 Apr. 1 00:00 | Node1 | 14.6 MW | 12.0 kV | — |
| | | Line1-2 | 14.6 MW | — | 1.22 kA |
| | | . . . | . . . | . . . | . . . |
| | . . . | . . . | . . . | . . . | . . . |
| Config-2 | 2030 Apr. 1 00:00 | Node1 | 15.0 MW | 12.0 kV | — |
| | | Line1-2 | 15.0 MW | — | 1.25 kA |
| | | . . . | . . . | . . . | . . . |
| | 2030 Apr. 1 00:00 | Node1 | 14.5 MW | 12.0 kV | — |
| | | Line1-2 | 14.5 MW | — | 1.21 kA |
| | | . . . | . . . | . . . | . . . |
| | . . . | . . . | . . . | . . . | . . . |
| . . . | . . . | . . . | . . . | . . . | . . . |

Returning to FIG. 7A, at step 213A, it is determined whether optimal power flow data have been generated for all grid configurations.

At step 214A, the analysis program generates boundary condition data, e.g., based on optimal power flow data. Boundary condition data is generated by extracting power and voltage of boundary equipment between the transmission grid and the distribution grid and, as shown in Table 4, may include power and voltage information for each predetermined unit time for each grid configuration.

At step 215A, the analysis program communicates the optimal power flow data to the evaluation program. In addition, the analysis program communicates the boundary condition data to an analysis program on the transmission side.

TABLE 4
Boundary condition data

| Config | Time | Power | Voltage |
|---|---|---|---|
| Config-1 | 2030 Apr. 1 00:00 | 15.1 MW | 12.0 kV |
| | 2030 Apr. 1 00:00 | 14.6 MW | 12.0 kV |
| | . . . | . . . | . . . |
| Config-2 | 2030 Apr. 1 00:00 | 15.0 MW | 12.0 kV |
| | 2030 Apr. 1 00:00 | 14.5 MW | 12.0 kV |
| | . . . | . . . | . . . |
| . . . | . . . | . . . | . . . |

FIG. 7B illustrates an exemplary process for an analysis component on a transmission side of a grid according to various embodiments of the present disclosure. Process 750 may begin at step 211B, when the analysis program on the transmission side receives future grid configuration data from the planning program on the transmission side and boundary condition data from the analysis program on the distribution side.

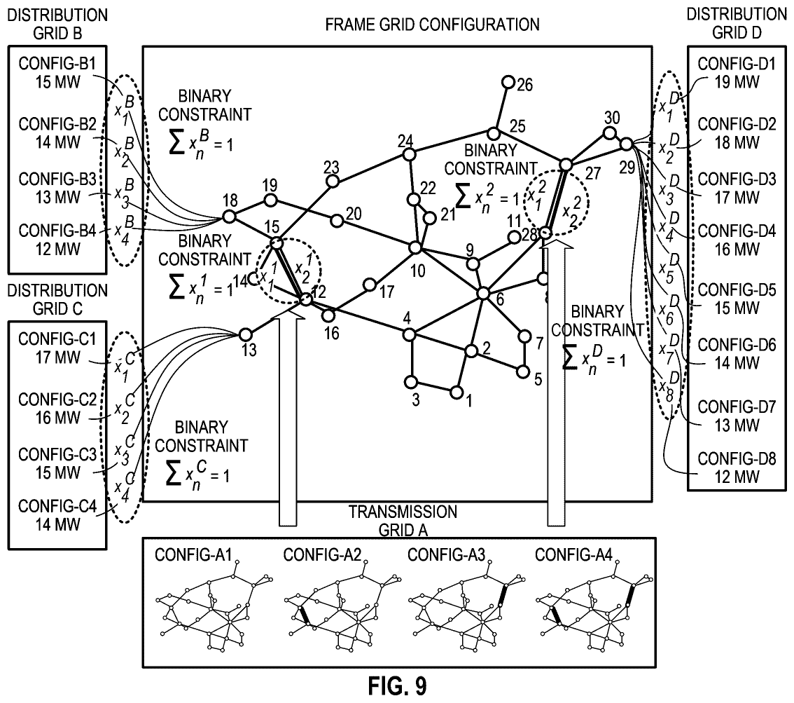

At step 212B, the analysis program generates frame grid configuration data based on future grid configuration data and boundary condition data. As indicated in exemplary figure FIG. 9, the frame grid configuration data is generated such as to include all grid configurations included in the future grid configuration data and all the boundary conditions included in the boundary condition data. For example, there are grid configurations in FIG. 9 in which reinforcement of Line 12-15 and reinforcement of Line 27-28 are candidates for grid measures in Grid A, such that, in frame grid configuration 800, lines before reinforcement and lines after reinforcement coexist to include all these grid configurations. In addition, since there are as many boundary conditions as there are grid configurations in Grids B, C, and D. All grid configurations on the distribution side are interconnected with Grid A in the frame grid configuration such as to include all of these boundary conditions.

At step 213B, the analysis program generates optimal grid configuration data based on frame grid configuration data. Optimal grid configuration data is generated by executing an optimal power flow calculation for the frame grid configuration based on a predetermined objective function and constraint conditions, and eliminating duplicate grid configurations, and it includes the optimal grid configuration for each grid as shown in Table 6. Here, the objective function is cost minimization, loss minimization, etc., and the constraint conditions are power flow constraints, capacity constraints, etc. In addition, in this process, in order to uniquely determine the grid measures and boundary conditions to be adopted, a 0/1 binary variable representing whether each grid measure and each boundary condition is adopted is incorporated into these objective functions and constraint conditions, and set binary constraints regarding the upper limit of each adoption. For example, in Table 5, the presence or absence of reinforcement for Line 12-15 and Line 27-28, and the presence or absence of boundary conditions for Grid B, C, and D are incorporated as binary variables, and a binary constraint is set in which the upper limit of adoption for each is set to 1.

TABLE 5
Optimal configuration data.

| | Grid A | Grid B | Grid C | Grid D |
|---|---|---|---|---|
| Datetime | | | | |
| 2030 Apr. 1 00:00 | Config-1 | Config-1 | Config-1 | Config-1 |
| 2030 Apr. 1 00:00 | Config-1 | Config-1 | Config-1 | Config-1 |
| . . . | . . . | . . . | . . . | . . . |
| 2040 Mar. 31 23:00 | Config-2 | Config-1 | Config-3 | Config-5 |

[symbol]

Eliminate duplicates

| | | | | |
|---|---|---|---|---|
| # | | | | |
| 1 | Config-1 | Config-1 | Config-1 | Config-1 |
| 2 | Config-1 | Config-1 | Config-1 | Config-2 |
| . . . | . . . | . . . | . . . | . . . |
| 10 | Config-2 | Config-1 | Config-3 | Config-5 |

Returning to FIG. 7B, at step 214B, the analysis program generates optimal power flow data based on optimal grid configuration data. Optimal power flow data is generated by executing optimal power flow calculation for each optimal grid configuration based on predetermined objective functions and constraint conditions, and it includes the power, voltage, and current of each equipment for each predetermined unit time (in this example, every hour) for each grid configuration as shown in Table 6. Here, the objective function is cost minimization, loss minimization, etc., and the constraint conditions are power flow constraints, capacity constraints, etc.

At step 215B, it is determined whether optimal power flow data have been generated for all optimal grid configurations.

Finally, at step 216B, the analysis program communicates the optimal power flow data to the evaluation program.

TABLE 6
Optimal power flow data.

| Config | Time | Object | Power | Voltage | Current |
|---|---|---|---|---|---|
| OptimalConfig-1 | 2030 Apr. | Node1 | 75.5 MW | 230.0 kV | — |
| | 1 00:00 | Line1-2 | 60.4 MW | — | 0.26 kA |
| | | . . . | . . . | . . . | . . . |
| | 2030 Apr. | Node1 | 73.0 MW | 230.0 kV | — |
| | 1 00:00 | Line1-2 | 58.4 MW | — | 0.25 kA |
| | | . . . | . . . | . . . | . . . |
| | . . . | . . . | . . . | . . . | . . . |
| OptimalConfig-2 | 2030 Apr. | Node1 | 75.0 MW | 230.0 kV | — |
| | 1 00:00 | Line1-2 | 60.0 MW | — | 0.26 kA |
| | | . . . | . . . | . . . | . . . |
| | 2030 Apr. | Node1 | 72.5 MW | 230.0 kV | — |
| | 1 00:00 | Line1-2 | 58.0 MW | — | 0.25 kA |
| | | . . . | . . . | . . . | . . . |
| | . . . | . . . | . . . | . . . | . . . |
| . . . | . . . | . . . | . . . | . . . | . . . |

FIG. 8A illustrates an exemplary process for an evaluation component on a distribution side according to various embodiments of the present disclosure. Process 900 may begin at step 311A, when the evaluation program receives future grid configuration data from the planning program and optimal power flow data from the analysis program.

At step 312A, the evaluation program generates investment and operation cost data based on future grid configuration data and optimal power flow data. Investment and operation cost data are generated by calculating the sum of capital investment costs (installation cost, reinforcement cost, etc.) and the sum of grid operation costs (generation cost, suppression cost, etc.) for each grid configuration. As shown in Table 7, this may include the investment cost, the operation cost, and the total cost for each predetermined unit time (e.g., yearly) for each grid configuration.

TABLE 7
Investment and operation cost data

| Config | Year | Investment | Operation | Total |
|---|---|---|---|---|
| Config-1 | 2030 | $0M | $200M | $200M |
| | 2031 | $0M | $210M | $210M |
| | . . . | . . . | . . . | . . . |
| | 2039 | $0M | $250M | $250M |
| Config-2 | 2030 | $100M | $120M | $220M |
| | 2031 | $100M | $122M | $222M |
| | . . . | . . . | . . . | . . . |
| | 2039 | $100M | $130M | $230M |
| . . . | . . . | . . . | . . . | . . . |

Returning to FIG. 8A, at step 313A, it is determined whether investment and operation cost data have been generated for all grid configurations.

At step 314A, the evaluation program generates differential cost data based on investment and operation cost data 320A. The differential cost data may be generated by calculating the cost difference between each future grid configuration and the current grid configuration. As shown in Table 8, this may include the investment cost difference, the operation cost difference, and the total cost difference for each predetermined unit time for each grid configuration.

TABLE 8
Differential cost data

| Config | Year | Investment | Operation | Total |
|---|---|---|---|---|
| Config-1 | 2030 | ±$0M | ±$0M | ±$0M |
| | 2031 | ±$0M | ±$0M | ±$0M |
| | . . . | . . . | . . . | . . . |
| | 2039 | ±$0M | ±$0M | ±$0M |
| Config-2 | 2030 | +$100M | −$80M | +$20M |
| | 2031 | +$100M | −$88M | +$12M |
| | . . . | . . . | . . . | . . . |
| | 2039 | +$100M | −$120M | −$20M |
| . . . | . . . | . . . | . . . | . . . |

Returning to FIG. 8A, at step 315A, the evaluation program communicates the differential cost data to an evaluation program on the transmission side.

At step 316A, the evaluation program receives differential cost data from the evaluation program on the transmission side.

At step 317A, the evaluation program generates grid plan data based on investment and operation cost data and the received differential cost data. The grid plan data is generated by arranging the future grid configurations in chronological order so that the total cost during the planning period is minimized based on the investment and operation cost. It includes the grid configuration for each predetermined unit time during the planning period (in this example, every year for 10 years) as shown in Table 9.

At step 318A, the evaluation program stores the grid plan data in memory.

TABLE 9
Grid plan data

| | 2030 | 2031 | . . . | 2038 | 2039 |
|---|---|---|---|---|---|
| Grid D | Config-D1 | Config-D1 | . . . | Config-D6 | Config-D6 |

FIG. 8B illustrates an exemplary process for an evaluation component on a transmission side according to various embodiments of the present disclosure. Process 950 may begin at step 311B, when the evaluation program receives future grid configuration data from the planning program and optimal power flow data from the analysis program on the transmission side, and differential cost data from the evaluation program on the distribution side.

At step 312B, the evaluation program generates investment and operation cost data based on the future grid configuration data and the optimal power flow data. Investment and operation cost data are generated by calculating the sum of capital investment costs (installation cost, reinforcement cost, etc.) and the sum of grid operation costs (generation cost, suppression cost, etc.) for each optimal grid configuration, and it includes the investment cost, the operation cost, and the total cost for each predetermined unit time (e.g., yearly) for each grid configuration as shown in Table 10.

TABLE 10
Investment and operation cost data

| Config | Year | Investment | Operation | Total |
|---|---|---|---|---|
| OptimalConfig-1 | 2030 | $0M | $1000M | $1000M |
| | 2031 | $0M | $1050M | $1050M |
| | . . . | . . . | . . . | . . . |
| | 2039 | $0M | $1250M | $1250M |
| OptimalConfig-2 | 2030 | $500M | $600M | $1100M |
| | 2031 | $500M | $610M | $1110M |
| | . . . | . . . | . . . | . . . |
| | 2039 | $500M | $650M | $1150M |
| . . . | . . . | . . . | . . . | . . . |

Returning to FIG. 8B, at step 313B, it is determined whether the investment and operation cost data have been generated for all optimal grid configurations.

At step 314B, the evaluation program generates differential cost data based on the investment and operation cost data, e.g., by calculating the cost difference between each future grid configuration and the current grid configuration. This may include the investment cost difference, the operation cost difference, and the total cost difference for each predetermined unit time for each optimal grid configuration, as shown in Table 11.

TABLE 11
Differential cost data

| Config | Year | Investment | Operation | Total |
|---|---|---|---|---|
| OptimalConfig-1 | 2030 | ±$0M | ±$0M | ±$0M |
| | 2031 | ±$0M | ±$0M | ±$0M |
| | . . . | . . . | . . . | . . . |
| | 2039 | ±$0M | ±$0M | ±$0M |
| OptimalConfig-2 | 2030 | +$500M | −$400M | +$100M |
| | 2031 | +$500M | −$440M | +$60M |
| | . . . | . . . | . . . | . . . |
| | 2039 | +$500M | −$600M | −$100M |
| . . . | . . . | . . . | . . . | . . . |

Returning to FIG. 8B, at step 315B, the evaluation program communicates the differential cost data to the evaluation program on the distribution side.

At step 316B, the evaluation program generates grid plan data based on investment and operation cost data and the differential cost data. The grid plan data may be generated by arranging the future grid configurations in chronological order such that the total cost during the planning period is minimized based on the investment and operation cost. This includes the grid configuration for each predetermined unit time during the planning period (here, yearly for 10 years), as shown in Table 12.

Finally, at step 317B, the evaluation program stores the grid plan data in memory.

TABLE 12
Grid plan data

| | 2030 | 2031 | . . . | 2038 | 2039 |
|---|---|---|---|---|---|
| Grid A | Config-A1 | Config-A1 | . . . | Config-A1 | Config-A2 |

One skilled in the art shall recognize that: (1) certain steps may optionally be performed; (2) steps may not be limited to the specific order set forth herein; (3) certain steps may be performed in different orders; and (4) certain steps may be done concurrently.

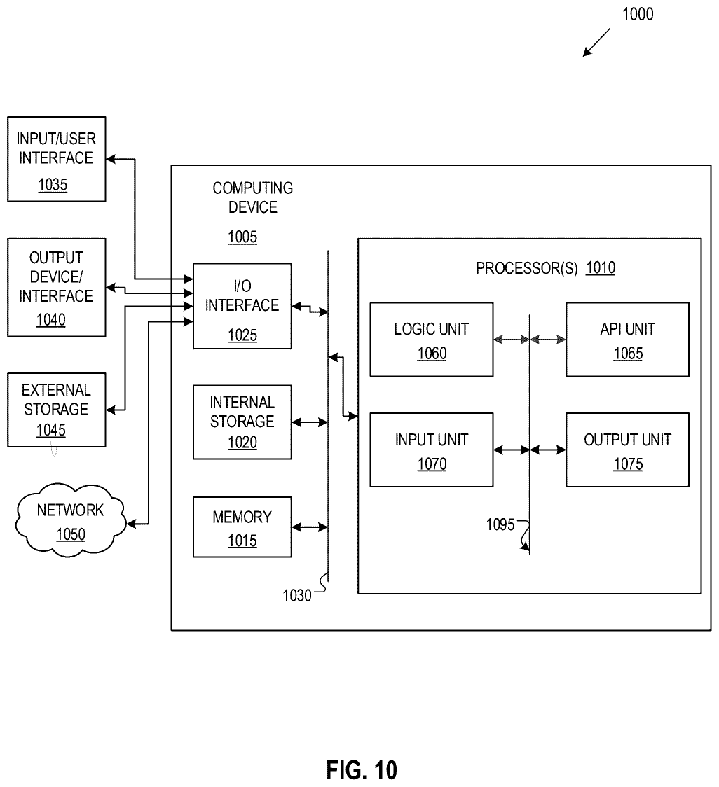

FIG. 10 illustrates an example computing environment with an example computer device suitable for use in some example implementations. Computer device 1005 in computing environment 1000 can include one or more processing units, cores, or processors 1010, memory 1015 (e.g., RAM, ROM, and/or the like), internal storage 1020 (e.g., magnetic, optical, solid-state storage, and/or organic), and/or I/O interface 1025, any of which can be coupled on a communication mechanism or bus 1030 for communicating information or embedded in the computer device 1005. I/O interface 1025 is also configured to receive images from cameras or provide images to projectors or displays, depending on the desired implementation.

Computer device 1005 can be communicatively coupled to input/user interface 1035 and output device/interface 1040. Either one or both of input/user interface 1035 and output device/interface 1040 can be a wired or wireless interface and can be detachable. Input/user interface 1035 may include any device, component, sensor, or interface, physical or virtual, that can be used to provide input (e.g., buttons, touch-screen interface, keyboard, a pointing/cursor control, microphone, camera, braille, motion sensor, optical reader, and/or the like). Output device/interface 1040 may include a display, television, monitor, printer, speaker, braille, or the like. In some example implementations, input/user interface 1035 and output device/interface 1040 can be embedded with or physically coupled to the computer device 1005. In other example implementations, other computer devices may function as or provide the functions of input/user interface 1035 and output device/interface 1040 for a computer device 1005.

Examples of computer device 1005 may include highly mobile devices (e.g., smartphones, devices in vehicles and other machines, devices carried by humans and animals, and the like), mobile devices (e.g., tablets, notebooks, laptops, personal computers, portable televisions, radios, and the like), and devices not designed for mobility (e.g., desktop computers, other computers, information kiosks, televisions with one or more processors embedded therein and/or coupled thereto, radios, and the like).

Computer device 1005 can be communicatively coupled (e.g., via I/O interface 1025) to external storage 1045 and network 1050 for communicating with any number of networked components, devices, and systems, including one or more computer devices of the same or different configurations. Computer device 1005 or any connected computer device can be functioning as, providing services of, or referred to as a server, client, thin server, general machine, special-purpose machine, or another label.

I/O interface 1025 can include wired and/or wireless interfaces using any communication or I/O protocols or standards (e.g., Ethernet, 802.11x, Universal System Bus, WiMax, modem, a cellular network protocol, and the like) for communicating information to and/or from at least all the connected components, devices, and network in computing environment 1000. Network 1050 can be any network or combination of networks (e.g., the Internet, local area network, wide area network, a telephonic network, a cellular network, a satellite network, and the like).

Computer device 1005 can use and/or communicate using computer-usable or computer-readable media, including transitory media and non-transitory media. Transitory media include transmission media (e.g., metal cables, fiber optics), signals, carrier waves, and the like. Non-transitory media include magnetic media (e.g., disks and tapes), optical media (e.g., CD ROM, digital video disks, Blu-ray disks), solid-state media (e.g., RAM, ROM, flash memory, solid-state storage), and other non-volatile storage or memory.

Computer device 1005 can be used to implement techniques, methods, applications, processes, or computer-executable instructions in some example computing environments. Computer-executable instructions can be retrieved from transitory media, and stored on and retrieved from non-transitory media. The executable instructions can originate from one or more of any programming, scripting, and machine languages (e.g., C, C++, C#, Java, Visual Basic, Python, Perl, JavaScript, and others).

Processor(s) 1010 can execute under any operating system (OS) (not shown), in a native or virtual environment. One or more applications can be deployed that include logic unit 1060, application programming interface (API) unit 1065, input unit 1070, output unit 1075, and inter-unit communication mechanism 1095 for the different units to communicate with each other, with the OS, and with other applications (not shown). The described units and elements can be varied in design, function, configuration, or implementation and are not limited to the descriptions provided. Processor(s) 1010 can be in the form of hardware processors such as central processing units (CPUs) or a combination of hardware and software units.

In some example implementations, when information or an execution instruction is received by API unit 1065, it may be communicated to one or more other units (e.g., logic unit 1060, input unit 1070, output unit 1075). In some instances, logic unit 1060 may be configured to control the information flow among the units and direct the services provided by API unit 1065, input unit 1070, and output unit 1075, in some example implementations described above. For example, the flow of one or more processes or implementations may be controlled by logic unit 1060 alone or in conjunction with API unit 1065. The input unit 1070 may be configured to obtain input for the calculations described in the example implementations, and the output unit 1075 may be configured to provide output based on the calculations described in example implementations.

Processor(s) 1010 can be configured to execute a method or computer instructions which can involve, at a planning component, performing steps for each of a transmission grid and a distribution grid, the steps including: in response to receiving grid equipment data and receiving demand and renewable energy RE information associated with a planning period, generating grid measure data; using the grid measure data to generate grid configurations; and communicating the grid configurations to an analysis component, as shown in FIG. 3, FIG. 4A, and FIG. 4B.

Processor(s) 1010 can be configured to execute, at the analysis component, steps for the distribution grid, the steps including: in response to receiving the grid configurations, determining, for each grid configuration, a first set of power flows for predetermined units of time within the planning period; using the power flows to obtain boundary condition data associated with boundaries between the distribution grid and the transmission grid; and communicating the first set of power flows to a distribution-side evaluation component; at the analysis component, performing steps for the transmission grid, the steps including: in response to receiving the grid configurations and the boundary condition data, generating, for each grid configuration, frame grid configuration data; using the frame grid configuration data to calculate optimal grid configuration data; using the optimal grid configuration data to generate a second set of power flows; and communicating the second set of power flows to a transmission-side evaluation component, as shown in FIG. 3, FIG. 7A, and FIG. 7B.

Processor(s) 1010 can be configured to execute, at the distribution-side evaluation component and the transmission-side evaluation component, steps including: in response to receiving the grid configurations and respective first set of power flows and second set of power flows, generating investment cost and operation cost data; computing and exchanging a differential cost for each grid configuration; and using the investment cost and operation cost data and the differential cost to generate a grid plan, as shown in FIG. 3, FIG. 8A, and FIG. 8B.

Some portions of the detailed description are presented in terms of algorithms and symbolic representations of operations within a computer. These algorithmic descriptions and symbolic representations are the means used by those skilled in the data processing arts to convey the essence of their innovations to others skilled in the art. An algorithm is a series of defined steps leading to a desired end state or result. In example implementations, the steps carried out require physical manipulations of tangible quantities to achieve a tangible result.

Unless specifically stated otherwise, as apparent from the discussion, it is appreciated that throughout the description, discussions utilizing terms such as “processing,” “computing,” “calculating,” “determining,” “displaying,” or the like, can include the actions and processes of a computer system or other information processing device that manipulates and transforms data represented as physical (electronic) quantities within the computer system's registers and memories into other data similarly represented as physical quantities within the computer system's memories or registers or other information storage, transmission or display devices.

Example implementations may also relate to an apparatus for performing the operations herein. This apparatus may be specially constructed for the required purposes, or it may include one or more general-purpose computers selectively activated or reconfigured by one or more computer programs. Such computer programs may be stored in a computer-readable medium, such as a computer-readable storage medium or a computer-readable signal medium. A computer-readable storage medium may involve tangible mediums such as optical disks, magnetic disks, read-only memories, random access memories, solid-state devices, drives, or any other types of tangible or non-transitory media suitable for storing electronic information. A computer-readable signal medium may include mediums such as carrier waves. The algorithms and displays presented herein are not inherently related to any particular computer or other apparatus. Computer programs can involve pure software implementations that involve instructions that perform the operations of the desired implementation.

Various general-purpose systems may be used with programs and modules in accordance with the examples herein, or it may prove convenient to construct a more specialized apparatus to perform desired method steps. In addition, the example implementations are not described with reference to any particular programming language. It will be appreciated that a variety of programming languages may be used to implement the techniques of the example implementations as described herein. The instructions of the programming language(s) may be executed by one or more processing devices, e.g., central processing units (CPUs), processors, or controllers.

As is known in the art, the operations described above can be performed by hardware, software, or some combination of software and hardware. Various aspects of the example implementations may be implemented using circuits and logic devices (hardware), while other aspects may be implemented using instructions stored on a machine-readable medium (software), which if executed by a processor, would cause the processor to perform a method to carry out implementations of the present application. Further, some example implementations of the present application may be performed solely in hardware, whereas other example implementations may be performed solely in software. Moreover, the various functions described can be performed in a single unit, or can be spread across a number of components in any number of ways. When performed by software, the methods may be executed by a processor, such as a general-purpose computer, based on instructions stored on a computer-readable medium. If desired, the instructions can be stored on the medium in a compressed and/or encrypted format.

Moreover, other implementations of the present application will be apparent to those skilled in the art from consideration of the specification and practice of the techniques of the present application. Various aspects and/or components of the described example implementations may be used singly or in any combination. It is intended that the specification and example implementations be considered as examples only, with the true scope and spirit of the present application being indicated by the following claims.

What is claimed is:

1. A grid planning method for transmission and distribution grids, the method comprising:
at a planning component, performing steps for each of a transmission grid and a distribution grid, the steps comprising:
in response to receiving grid equipment data and receiving demand and renewable energy (RE) information associated with a planning period, generating grid measure data;
using the grid measure data to generate grid configurations; and
communicating the grid configurations to an analysis component;
at the analysis component, performing steps for the distribution grid, the steps comprising:
in response to receiving the grid configurations, determining, for each grid configuration, a first set of power flows for predetermined units of time within the planning period;
using the power flows to obtain boundary condition data associated with boundaries between the distribution grid and the transmission grid; and
communicating the first set of power flows to a distribution-side evaluation component;
at the analysis component, performing steps for the transmission grid, the steps comprising:
in response to receiving the grid configurations and the boundary condition data, generating, for each grid configuration, frame grid configuration data;
using the frame grid configuration data to calculate optimal grid configuration data;
using the optimal grid configuration data to generate a second set of power flows; and
communicating the second set of power flows to a transmission-side evaluation component;
at the distribution-side evaluation component and the transmission-side evaluation component, performing steps comprising:
in response to receiving the grid configurations and respective first set of power flows and second set of power flows, generating investment cost and operation cost data;
computing and exchanging a differential cost for each grid configuration; and
using the investment cost and operation cost data and the differential cost to generate a grid plan.

2. The method according to claim 1, wherein the equipment data is received from an asset management device, and the demand and renewable energy (RE) information is received from a forecast device.

3. The method according to claim 1, further comprising using the grid measure data to satisfy a reliability standard that comprises at least one of a load factor and voltage violation rate associated with the demand and RE scenario data.

4. The method according to claim 2, wherein the grid measure data identifies at least one of a date, a device, or an action.

5. The method according to claim 1, wherein the frame grid configuration data comprises all the grid configurations and all the boundary conditions included in the boundary condition data.

6. The method according to claim 1, wherein generating the second set of power flows comprises eliminating duplicate grid configurations.

7. The method according to claim 1, wherein generating the second set of power flows comprises applying to each grid configuration a constraint condition and an objective function that comprises at least one of a cost minimization or a loss minimization.

8. The method according to claim 7, wherein the constraint condition comprises at least one of a power flow constraint or a capacity constraint.

9. The method according to claim 8, wherein, for each grid configuration, at least one of the objective function or the constraint condition comprises at least one of a power, a voltage, or a current for each predetermined unit time.

10. The method according to claim 1, further comprising determining whether each grid measure and each boundary condition is incorporated into an objective function and a binary constraint condition to identify grid measures and boundary conditions.

11. The method according to claim 10, wherein the binary constraint condition is set based on a threshold and the boundary condition data is generated by using a power and/or a voltage associated with equipment at a boundary between the transmission grid and the distribution grid.

12. The method according to claim 11, wherein the power and/or voltage comprises a power and/or voltage for each predetermined unit time for each grid configuration.

13. The method according to claim 1, further comprising communicating, by the distribution side, the boundary condition data to the analysis program on the transmission side.

14. The method according to claim 1, wherein the differential cost data is generated by calculating a cost difference between each grid configuration and the current grid configuration.

15. The method according to claim 14, wherein the differential cost data comprises an investment cost difference, an operation cost difference, and a total cost difference for each predetermined unit time for each grid configuration.

16. The method according to claim 1, wherein the investment cost comprises at least one of an installation cost or a reinforcement cost for each grid configuration.

17. The method according to claim 1, wherein the operation cost data comprises at least one of a generation cost or a suppression cost for each grid configuration.

18. The method according to claim 1, wherein the grid plan comprises using a time-series transition of each grid configuration.

19. A non-transitory computer-readable medium for storing instructions for executing a process, the instructions comprising:
in response to receiving grid equipment data and demand and renewable energy (RE) information associated with a planning period, generating grid measure data;
using the grid measure data to generate grid configurations;
determining, for each grid configuration, a first set of power flows for predetermined units of time within the planning period;
using the power flows to obtain boundary condition data associated with boundaries between the distribution grid and the transmission grid; and
in response to receiving the grid configurations and the boundary condition data, generating, for each grid configuration, frame grid configuration data;
using the frame grid configuration data to calculate optimal grid configuration data;
using the optimal grid configuration data to generate a second set of power flows;
in response to receiving the grid configurations and respective first set of power flows and second set of power flows, generating investment cost and operation cost data;
computing and exchanging a differential cost for each grid configuration; and
using the investment cost and operation cost data and the differential cost to generate a grid plan.

20. An apparatus, comprising:
one or more processors, configured to perform steps comprising:
at a planning component, performing steps for each of a transmission grid and a distribution grid, the steps comprising:
in response to receiving grid equipment data and receiving demand and renewable energy (RE) information associated with a planning period, generating grid measure data;
using the grid measure data to generate grid configurations; and
communicating the grid configurations to an analysis component;
at the analysis component, performing steps for the distribution grid, the steps comprising:
in response to receiving the grid configurations, determining, for each grid configuration, a first set of power flows for predetermined units of time within the planning period;
using the power flows to obtain boundary condition data associated with boundaries between the distribution grid and the transmission grid; and
communicating the first set of power flows to a distribution-side evaluation component;
at the analysis component, performing steps for the transmission grid, the steps comprising:
in response to receiving the grid configurations and the boundary condition data, generating, for each grid configuration, frame grid configuration data;
using the frame grid configuration data to calculate optimal grid configuration data;
using the optimal grid configuration data to generate a second set of power flows; and
communicating the second set of power flows to a transmission-side evaluation component;
at the distribution-side evaluation component and the transmission-side evaluation component, performing steps comprising:
in response to receiving the grid configurations and respective first set of power flows and second set of power flows, generating investment cost and operation cost data;
computing and exchanging a differential cost for each grid configuration; and
using the investment cost and operation cost data and the differential cost to generate a grid plan.
